(19) United States
(12) Patent Application Publication
(10) Pub. No.: US 2005/0226283 A1
(43) Pub. Date: Oct. 13, 2005

(54) SINGLE-MODE SEMICONDUCTOR LASER WITH INTEGRATED OPTICAL WAVEGUIDE FILTER

(75) Inventor: Jian-Jun He, Ottawa (CA)

Correspondence Address: Jian-Jun He, 40 College Circle, Ottawa, K1K4R8, CA

(73) Assignee: LIGHTIP TECHNOLOGIES INC., Ottawa (CA)

(21) Appl. No.: 10/907,495

(22) Filed: Apr. 4, 2005

Related U.S. Application Data
(60) Provisional application No. 60/559,283, filed on Apr. 5, 2004.

(51) Int. Cl. H01S 3/10; H01S 5/00

(52) U.S. Cl. 372/20; 372/50.1

(57) ABSTRACT

A monolithic single-mode semiconductor laser comprises three coupled Fabry-Perot cavities in tandem, each separated by a vertically etched air gap of a size that is substantially equal to an odd-integer multiple of quarter-wavelength. The middle cavity is actively pumped to provide gains to the combined cavity laser. The other cavities are substantially transparent and act as an optical filter to select one of the longitudinal modes of the middle cavity as the lasing mode. The lengths of the two passive cavities are substantially different so that a narrow filtering function with a large free spectral range is obtained for optimal mode selectivity.

### RELATED APPLICATIONS

This application claims benefit from U.S. Provisional Patent Application Ser. No. 60/559,283, filed on Apr. 5, 2004, entitled “Single-mode Semiconductor Laser”.

### FIELD OF THE INVENTION

This invention relates generally to a semiconductor laser, and more particularly to a single-mode semiconductor laser utilizing monolithically integrated optical waveguide etalon filters.

### BACKGROUND OF THE INVENTION

Semiconductor lasers have been widely used in fiber-optic communication systems. They are also important components as light sources for optical disks, optical sensing, and biomedical applications. Apart from vertical-cavity surface emitting lasers (VCSEL), most commonly used edge-emitting laser diodes includes Fabry-Perot type and distributed-feedback (DFB) type. The Fabry-Perot lasers are simple to fabricate and inexpensive, but are usually multimode and inadequate for high-speed long-haul optical communications. The DFB lasers incorporates a grating in the laser cavity so that it operates with a single wavelength in a single longitudinal mode and consequently suitable for long-distance fiber transmission. However, since it involves a grating patterning step and an additional epitaxial growth in the fabrication process, the DFB lasers are much more expensive than Fabry-Perot lasers.

With the deployment of fiber-to-the premise (FTTP) technology for broadband access and the spread of dense wavelength division multiplexing (DWDM) in metro and local networks, single-mode and low-cost semiconductor lasers have become more important. It is highly desirable to have single-mode semiconductor lasers that have a performance similar to that of DFB lasers but with a manufacturing cost similar to that of Fabry-Perot lasers. It is desirable that the laser can be easily integrated with a photodetector that allows power monitoring as well as on-wafer testing during the manufacturing process. It is also desirable that the laser can be easily integrated with a high-speed modulator that produces a low wavelength chirp.

It is an object of the present invention to provide a monolithically integrated single-mode semiconductor laser that has the above features with the advantages of compactness, simple fabrication process and low cost.

### SUMMARY OF THE INVENTION

In accordance with the invention, there is provided, a semiconductor laser comprising:
an active optical cavity having two partially reflecting elements and an active waveguide,
said active waveguide being sandwiched between a pair of electrodes for injecting current to provide optical gain,
a first passive optical etalon filter having two partially reflecting elements, said first passive optical etalon filter being coupled with the active optical cavity through a common partially reflecting element,
a second passive optical etalon filter having two partially reflecting elements, said second passive optical etalon filter being coupled with the active optical cavity through a common partially reflecting element,
wherein the first and the second passive optical etalon filters act as wavelength-selective reflectors to select one of the longitudinal modes of the active optical cavity as the lasing mode.

### BRIEF DESCRIPTION OF THE DRAWINGS

FIG. 1a is a prior art semiconductor laser based on a Fabry-Perot cavity

FIG. 1b is a prior art semiconductor laser based on a DFB grating.

FIG. 2 is a schematic drawing of an integrated single-mode semiconductor laser in accordance with one embodiment of the present invention.

FIG. 3 is the reflectivity and transmission coefficients of an air gap as a function of the gap size at 1550 nm wavelength.

FIG. 4a is the reflectivity spectra of two etalon filters each with a 5λ/4 etched air gap on one end and a cleaved facet on the other for a cavity length of Lₚ₁=20 μm (solid line) and Lₚ₂=61.25 μm (dashed line).

FIG. 4b is the product of the two reflectivity spectra of FIG. 4a.

FIG. 5 is the small signal gain spectrum of a semiconductor laser of the present invention with the active cavity length L=274.3 μm, and two passive waveguide etalon filters with cavity lengths Lₚ₁=20 μm and Lₚ₂=61.25 μm, which is calculated at the lasing threshold of the mode at 1550.12 nm with a gain coefficient g=4.35 cm⁻¹.

FIG. 6 is the threshold gains of different modes of the semiconductor laser of FIG. 5.

FIG. 7 is a schematic drawing of an integrated single-mode semiconductor laser in accordance with another embodiment of the present invention.

### DETAILED DESCRIPTION

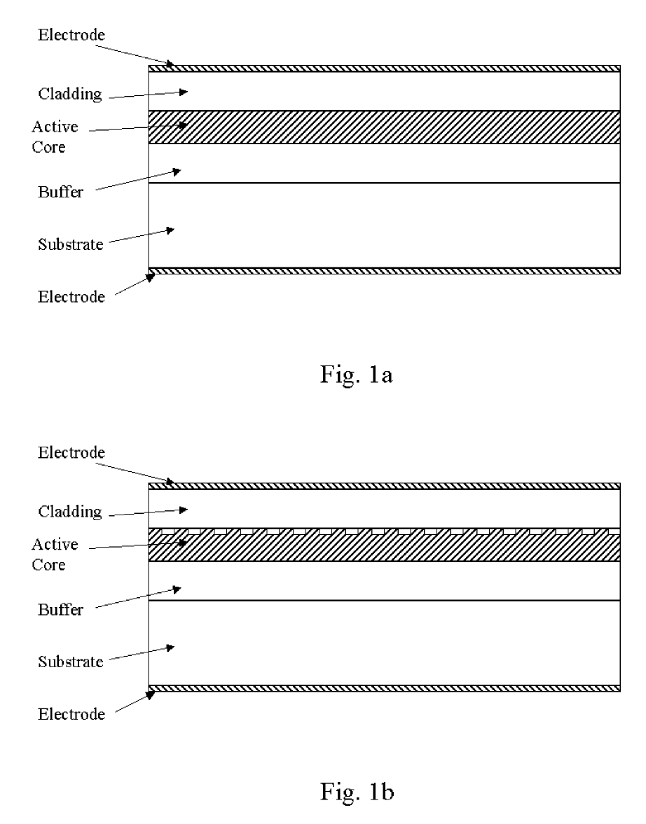

FIG. 1a is a schematic drawing of a prior-art semiconductor Fabry-Perot laser. The light bounces back and forth between two mirrors, which are formed by cleaving the facets of the semiconductor crystal. The waveguide region between the two mirrors is pumped electrically with current injection to provide amplification of light. Because of the periodic longitudinal mode structure of the Fabry-Perot cavity, the mode selectivity is only provided by the spectral distribution of the material gain. Due to spacial hole-burning effect, the laser is usually multimode with unstable intensity distribution between different modes.

FIG. 1b is a schematic drawing of another prior-art semiconductor laser based on distributed feedback (DFB) grating. Unlike a Fabry-Perot laser, a DFB laser has a grating etched into the gain region. This grating serves the purpose of stabilizing the frequency of the laser, making the laser single-mode with a precise wavelength for applications in fibre-optic transmission systems. However, the fabrication process is much more complicated than that of a Fabry-Perot laser because of an additional grating patterning step and required epitaxial overgrowth.

In the past decade, significant progress has been made in dry-etching technologies for fabricating deep, vertical and smooth etched facets. As an example, excellent results on the etched facet quality in InP based material system were reported by J.-J. He, B. Lamontagne, A. Delage, L. Erickson, M. Davies, E. S. Koteles, in a paper entitled “Monolithic integrated wavelength demultiplexer based on a waveguide Rowland circle grating in InGaAsP/InP”, J. Lightwave Tech. Vol. 16, pp. 631-638, 1998. One of the applications for high-quality etched facets is waveguide based echelle grating devices, which has been commercially developed. The maturity of fabrication technology for vertical and smooth etched facets and air gaps has provided the basis in terms of manufacturability for the devices of the present invention.

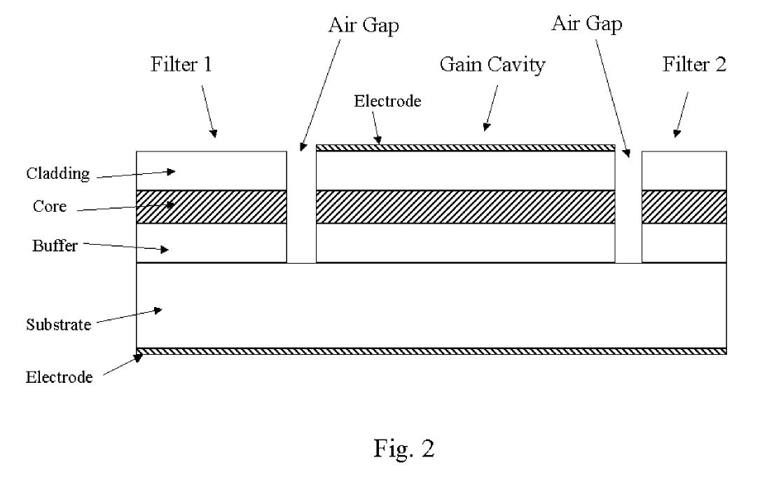

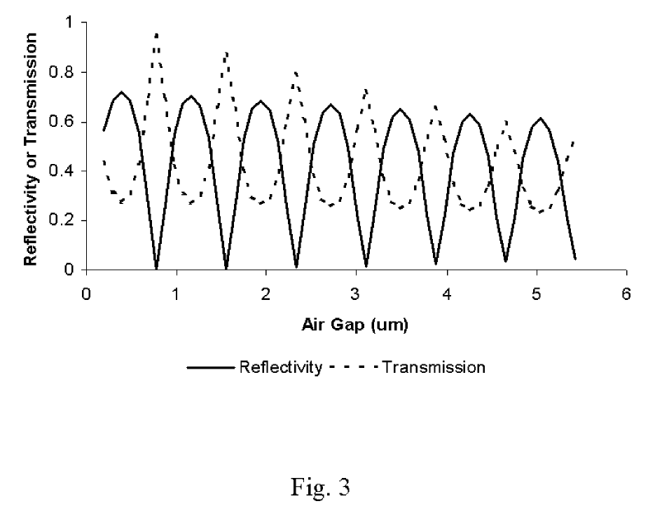

FIG. 2 illustrates a monolithic single-mode semiconductor laser in accordance with one embodiment of the present invention. It comprises three coupled Fabry-Perot cavities in tandem, each separated by a vertically etched air gap of a size that is substantially equal to an odd-integer multiple of quarter-wavelength. The middle cavity (called active cavity) is actively pumped to provide an optical gain to the laser, and to produce a series of equally spaced longitudinal modes. The other cavities (called passive cavities or etalon filters) are substantially transparent and act as optical filters to select one of the modes of the middle cavity as the lasing mode. The lengths of the two passive cavities are substantially different so that a narrow filtering function with a large free spectral range is obtained for optimal mode selectivity.

The waveguide structure generally consists of a buffer layer, a waveguide core layer that also provides gain when electrically pumped, and an upper cladding layer, deposited on a substrate. An electrode layer is deposited on the top surface. The backside of the substrate is also deposited with another metal electrode layer as a ground plane. The electrodes provide a means for injecting current to produce an optical gain in the case of the middle active cavity. In the case of the passive etalon filters, electrodes are optionally deposited to provide an electrical means to change the refractive index and absorption of the waveguide. Preferably the waveguide core layer comprises multiple quantum wells as in conventional laser structures and the layers are appropriately doped. In the transverse direction, standard ridge or rib waveguides are formed to laterally confine the optical mode.

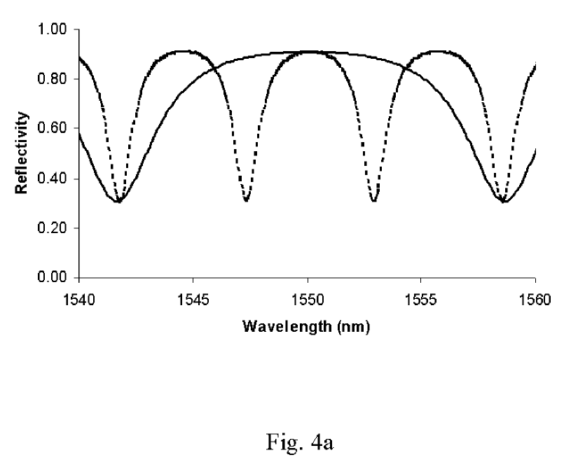

The air gaps in the structure act as partially reflecting mirrors for the cavities. In order to achieve high reflectivity, the gap size must be substantially equal to an odd-integer multiple of the quarter-wavelength, i.e., λ/4, 3λ/4, 5λ/4, . . . etc. FIG. 3 shows the reflectivity and transmission coefficient of an air gap as a function of the gap size at 1550 nm wavelength. If the gap size is equal to an even-integer multiple of the quarter-wavelength (i.e. λ/2, λ, 3λ/2, . . . etc), the reflectivity of the air gap becomes almost negligible.

Theoretically, the best performance is obtained with the smallest air gap, i.e., λ/4. This is because the loss at the unguided air gap increases as the gap size increases, due to beam divergence. Consequently, the peak reflectivity decreases, as can be seen in FIG. 3. On the other hand, the fabrication becomes more challenging as the gap size decreases, since a λ/4 gap is only 0.3875 μm for 1550 nm wavelength. A 5λ/4 to 9λ/4 air gap, corresponding to a size of 1.94 μm to 3.49 μm, can be a good compromise. The error tolerance on the gap should be in the order of ±0.1 μm for InP based material system, regardless of the gap size. This is achievable with current state of the art fabrication technology.

According to a preferred embodiment of the present invention, two passive Fabry-Perot cavities are used to collectively serve as an optical filter to select only one of the longitudinal modes to lase. The passive cavities are implemented in an integrated manner, one on each side of the active cavity, as shown in FIG. 2. The term “passive” here means that no gain is intentionally provided. However, optionally, electrical means may be provided to change the refractive index so that the central wavelengths of the filters are aligned to the lasing mode.

The free spectral range of an etalon filter is related to its length by Δf=c/2 n_{g}Lₚ, where c is the light velocity in vacuum, n_{g} the effective group refractive index of the waveguide, and Lₚ the passive filter cavity length. In order not to have more than one mode lasing simultaneously, Δf_{c} should be at least comparable to the spectral width of the material gain window. This requires that the filter cavity length to be small. On the other hand, a short cavity results in a broad filter function, which leads to a low mode selectivity for adjacent modes.

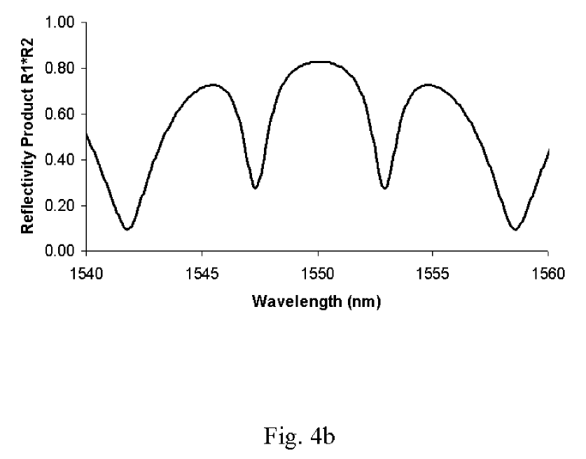

To improve the mode selectivity, two etalon filters of substantially different lengths are used, one at each side of the active cavity, as schematically shown in FIG. 2. By combining two etalon filters of different lengths, a narrow filtering function with a large free spectral range can be achieved. FIG. 4a gives the reflectivity spectra of two etalon filters, each comprising a transparent waveguide bounded by a 5λ/4 air gap on one end and a cleaved facet on the other, for cavity lengths Lₚ₁=20 μm and Lₚ₂=61.25 μm. In the numerical examples, the effective refractive index of the waveguide is assumed to be 3.5. FIG. 4b shows the product of the two reflectivity spectra, which represents the filtering function for selecting the lasing mode. The mode of the active cavity at the peak of this spectral function will have the lowest lasing threshold.

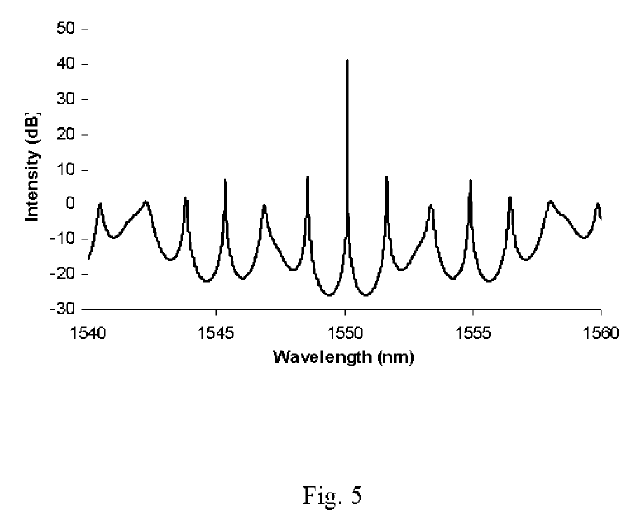

FIG. 5 shows the small signal gain spectra of the complete laser structure including the above two etalon filters and an active cavitiy of length L=214.3 μm. It is calculated at the lasing threshold of the mode at 1550.12 nm with a gain coefficient g=4.35 cm⁻¹.

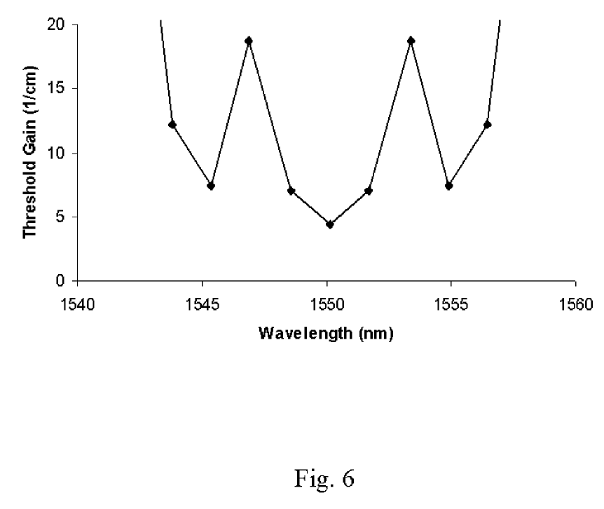

The mode selectivity of the laser can be characterized by threshold differences between the side modes and the main mode. FIG. 6 shows the lasing thresholds for different modes. The lowest threshold for side modes is about 7 cm⁻¹ in this example. A threshold difference as large as 61% is achieved between the side modes and the main mode. The spectral gain distribution of the active waveguide material is not considered in the above calculations, which would further increase the mode selectivity.

Obviously, a more complex filter can be designed by using multiple waveguide segments and air gaps that produce a narrow reflectivity peak and a large free spectral range.

For the passive cavities, the waveguide material needs to be substantially transparent. The integration of the passive waveguide with the active waveguide can be done by using the etch-and-regrowth technique or a post-growth bandgap engineering method such as quantum well intermixing. An alternative is to pump active laser material close to transparency.

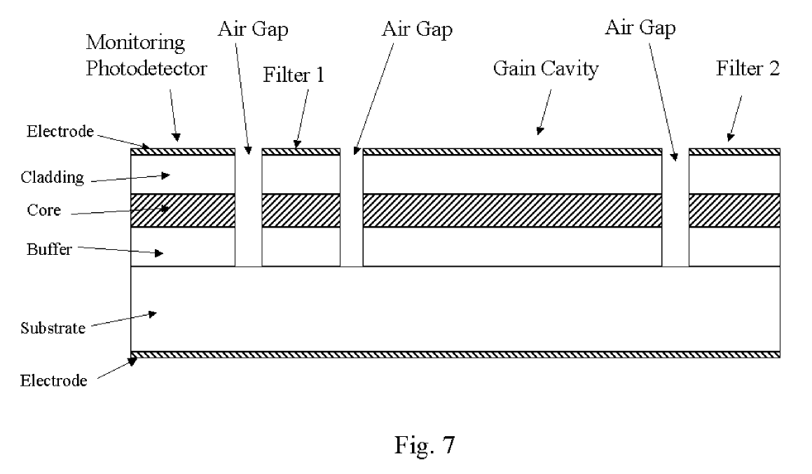

A monitoring photodetector can be optionally integrated, as shown in FIG. 7. The photodiode is separated from the adjacent cavity by another air gap. An etched facet can also be used to replace the cleaved front facet of the laser. The monitoring photodetector not only serves as a power monitor of the laser during operation, but can also be used for on-wafer testing during the manufacturing process, thus greatly reducing the labor cost associated with chip testing.

The etalon filter incorporated in the rear reflector of the laser can be optionally sandwiched between a pair of electrodes for applying an electrical signal (either a current injection or a reverse biased voltage) to change the absorption coefficient of the waveguide between the electrodes and consequently to change the reflectivity of the rear reflector. This results in the modulation of the Q-factor of the laser cavity and the lasing threshold, and consequently the output power.

Numerous other embodiments can be envisaged without departing from the spirit and scope of the invention. For example, one of the passive etalon filters can be omitted. The single air gap separating the cavities can be replaced by multiple air gaps. The gaps can be filled with a material of intermediate refractive index such as silicon oxide or silicon nitride.

1. A semiconductor laser comprising:
an active optical cavity having two partially reflecting elements and an active waveguide, said active waveguide being sandwiched between a pair of electrodes for injecting current to provide optical gain,
a first passive optical etalon filter having two partially reflecting elements, said first passive optical etalon filter being coupled with the active optical cavity through a common partially reflecting element,
a second passive optical etalon filter having two partially reflecting elements, said second passive optical etalon filter being coupled with the active optical cavity through a common partially reflecting element,
wherein the first and the second passive optical etalon filters act as wavelength-selective reflectors to select one of the longitudinal modes of the active optical cavity as the lasing mode.

2. A semiconductor laser as defined in claim 1, wherein the active optical cavity and the passive optical etalon filters are coupled through air gaps.

3. A semiconductor laser as defined in claim 2, wherein the air gaps have vertically-etched sidewalls.

4. A semiconductor laser as defined in claim 3, wherein the air gaps are of a size that is substantially equal to an odd-integer multiple of a quarter-wavelength.

5. A semiconductor laser as defined in claim 1, wherein the first and the second passive optical etalon filters have substantially different lengths for producing a narrow filtering function with a large free spectral range.

6. A semiconductor laser as defined in claim 1, wherein at least one of the first and the second passive optical etalon filters comprises a substantially transparent waveguide, said waveguide being sandwiched between a pair of electrodes for providing an electrical means to vary the effective refractive index of the waveguide and consequently to tune the wavelength of said at least one of the optical filters.

7. A semiconductor laser as defined in claim 1, wherein at least one of the first and the second passive optical etalon filters comprises an electro-absorptive waveguide, said waveguide being sandwiched between a pair of electrodes for providing an electrical means to vary the absorption of the waveguide and consequently to modulate the output power of the laser.

8. A semiconductor laser as defined in claim 1, further comprising a monitoring photodetector coupled to the second passive optical etalon filter through an etched air gap.

9. A semiconductor laser comprising:
a first optical waveguide bounded by two partially reflecting elements, said first optical waveguide being sandwiched between a pair of electrodes for injecting current to provide optical gain,
a second optical waveguide bounded by two partially reflecting elements, said second optical waveguide being coupled with the first optical waveguide through a common partially reflecting element,
wherein the second optical waveguide is substantially transparent and, in combination with two partially reflecting elements, acts as a wavelength-selective reflector to reduce the number of lasing modes of the laser.

10. A semiconductor laser as defined in claim 9, wherein the first optical waveguide and the second optical waveguide are coupled through an air gap.

11. A semiconductor laser as defined in claim 10, wherein the air gap between the first and the second waveguides has vertically-etched sidewalls.

12. A semiconductor laser as defined in claim 11, wherein the air gap between the first and the second waveguides is of a size that is substantially equal to an odd-integer multiple of a quarter-wavelength.

13. A semiconductor laser as defined in claim 9, wherein the second optical waveguide is sandwiched between a pair of electrodes for providing an electrical means to vary the effective refractive index of the waveguide and consequently to tune the wavelength of the laser.

14. A semiconductor laser as defined in claim 9, further comprising a monitoring photodetector waveguide coupled to one of the first and the second optical waveguides through an etched air gap.

15. A semiconductor laser as defined in claim 9, further comprising a third optical waveguide bounded by two partially reflecting elements, said third optical waveguide being coupled with the first optical waveguide through a common partially reflecting element.

16. A semiconductor laser as defined in claim 15, wherein the first optical waveguide and the third optical waveguide are coupled through an air gap having vertically-etched sidewalls and being of a size that is substantially equal to an odd-integer multiple of a quarter-wavelength.

17. A semiconductor laser as defined in claim 15, wherein the second and the third optical waveguides have substantially different lengths for producing a narrow filtering function with a large free spectral range.

18. A semiconductor laser as defined in claim 17, wherein one of the second and the third optical waveguides has a length that is at least double of the length of the other.

19. A semiconductor laser as defined in claim 15, wherein the third optical waveguide is sandwiched between a pair of electrodes for providing an electrical means to vary the absorption of the waveguide and consequently to modulate the output power of the laser.
